(19) United States
(12) Patent Application Publication
(10) Pub. No.: US 2023/0410905 A1
(43) Pub. Date: Dec. 21, 2023

(54) SPLIT FOOTER TOPOLOGY TO IMPROVE VMIN AND LEAKAGE POWER FOR REGISTER FILE AND READ ONLY MEMORY DESIGNS

(71) Applicant: Intel Corporation, Santa Clara, CA (US)

(72) Inventors: Arindrajit Ghosh, College Station, TX (US); Gaurav Kabra, Bangalore (IN)

(21) Appl. No.: 17/843,211

(22) Filed: Jun. 17, 2022

(51) Int. Cl. G11C 16/04; G11C 16/08; G11C 16/24; G11C 16/34; G11C 16/26

(52) U.S. Cl. CPC G11C 16/0433; G11C 16/08; G11C 16/24; G11C 16/3404; G11C 16/26

(57) ABSTRACT

Embodiments herein relate to a memory device in which a grounding footer transistor is provided for each column of memory cells in an array of memory cells to reduce leakage current in a read operation. Each column of memory cells further includes a column select transistor, where a control gate of the column select transistor is coupled to a control gate of the grounding footer transistor. For a selected column in a read operation, the column select transistor and grounding footer transistor are turned on, while for the remaining unselected columns, the column select transistors and grounding footer transistors are turned off.

### FIELD

The present application generally relates to the field of memory devices and more particularly, to memory array and an associated read operation.

### BACKGROUND

Memory devices include both volatile and non-volatile memory cells. The memory cells can be arranged in an array where word lines and bit lines allow access to the memory cells. Furthermore, a read operation for such memory cells can rely on sensing a voltage on a bit line. However, various challenges are presented in operating such devices.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts an example arrangement of groups of cells in a memory device, in accordance with various embodiments.

FIG. 2 depicts an example circuit diagram for one of the groups of cells of FIG. 1, where a footer transistor is not used, as a first comparative example, in accordance with various embodiments.

FIG. 3A depicts a current leakage model for the circuit of FIG. 2 in a Read-0 operation, in accordance with various embodiments.

FIG. 3B depicts an equivalent of the current leakage model of FIG. 3A, in accordance with various embodiments.

FIG. 4 depicts an example circuit diagram for one of the groups of cells of FIG. 1, where a common footer transistor is used, as a second comparative example, in accordance with various embodiments.

FIG. 5A depicts a current leakage model for the circuit of FIG. 4, in accordance with various embodiments.

FIG. 5B depicts an equivalent of the current leakage model of FIG. 5A, in accordance with various embodiments.

FIG. 6 depicts a table indicating a functional Vmin summary for both the circuits of FIG. 3 with no footer transistor and FIG. 4 with a common footer transistor, in accordance with various embodiments.

FIG. 7 depicts a table indicating an ideal leakage power comparison, comparing the circuit of FIG. 2 with no footer transistor to the circuit of FIG. 4 with a common footer transistor, in accordance with various embodiments.

FIG. 8 depicts plots of voltage versus time, indicating a leakage path discharge time in a Read-0 operation, comparing the circuit of FIG. 4 with a common footer transistor (plot 800) with the circuit of FIG. 10 with a separate respective footer transistor for each column (plot 810), e.g., a split footer, in accordance with various embodiments.

FIG. 9 depicts plots of leakage power versus time, and percent improvement in leakage power versus time, comparing the circuit of FIG. 4 with a common footer transistor (plot 900) to the circuit of FIG. 10 with a separate respective footer transistor for each column (plot 910), in accordance with various embodiments.

FIG. 10 depicts an example circuit diagram for one of the groups of cells of FIG. 1, where a separate respective footer transistor is used for each column, e.g., a split footer, in accordance with various embodiments.

FIG. 11A depicts a current leakage model for the circuit of FIG. 10, in accordance with various embodiments.

FIG. 11B depicts an equivalent of the current leakage model of FIG. 11A, in accordance with various embodiments.

FIG. 12 depicts a table indicating a Vmin, comparing the circuit of FIG. 4 with a common footer transistor to the circuit of FIG. 10 with a separate respective footer transistor for each column, in accordance with various embodiments.

FIG. 13 depicts a table indicating performance, comparing the circuit of FIG. 4 with a common footer transistor to the circuit of FIG. 10 with a separate respective footer transistor for each column, in accordance with various embodiments.

FIG. 14 depicts a table indicating a footer device size, resistance (R) and capacitance (C), comparing the circuit of FIG. 4 with a common footer transistor to the circuit of FIG. 10 with a separate respective footer transistor for each column, in accordance with various embodiments.

FIG. 15 depicts plots of an LBL bit line delay versus supply voltage, comparing the circuit of FIG. 4 with a common footer transistor (plot 1500) to the circuit of FIG. 10 with a separate respective footer transistor for each column (plot 1510), in accordance with various embodiments.

FIG. 16 depicts a table indicating a current leakage advantage, comparing the case of common footer transistor or split footer transistor as in FIG. 4 or 10, respectively, to the case with no footer transistor as in FIG. 2, in accordance with various embodiments.

FIG. 17 depicts a flowchart of an example method for performing a read operation in the circuit of FIG. 10, in accordance with various embodiments.

FIG. 18 illustrates an example of components that may be present in a computing system 1850 for implementing the techniques (e.g., operations, processes, methods, and methodologies) described herein.

### DETAILED DESCRIPTION

In the following detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

As mentioned at the outset, various challenges are presented in operating memory devices. One challenge is to minimum leakage current. During read operations, various current leakage paths may be present which reduce performance by increasing power consumption. Read time can also be adversely affected. Leakage paths can be present in arrays of volatile or non-volatile memory cells. Examples of volatile memory include random access memory (RAM) and examples of non-volatile memory include read-only memory (ROM) and register files.

For example, a memory array may include columns of memory cells coupled to respective bit lines and a respective column select transistor, which may be used to control charging and discharging of the bit line in a read operation. When the column select transistor is turned on, the bit line can be pre-charged by a power supply voltage. A selected word line voltage can then be elevated while the column select transistor remains turned on to allow a discharge of the bit line to be detected. The amount of discharge indicates a state of a selected memory cell, e.g., 0 or 1. In one approach, a 1 bit is associated with a high bit line voltage with little discharge and a 0 bit is associated with a low bit line voltage with substantial discharge.

Leakage paths may be present in the column select transistors and the memory cells.

The techniques herein address the above and other issues.

In one aspect, a memory device is provided in which a footer transistor or other switch is provided for each column of memory cells in an array of memory cells to reduce leakage current in a read operation. Each column of memory cells further includes a column select transistor, where a control gate of the column select transistor is coupled to a control gate of the footer transistor, so that the two transistors are turned on or off together by a common control signal. For a selected column in a read operation, the column select transistor and footer transistor of the selected column are turned on, while for the remaining unselected columns, the column select transistors and footer transistors are turned off. When a footer transistor is turned on, it connects the memory cells of the columns to ground (e.g., 0 V) or other fixed voltage.

These and other features will be apparent in view of the following discussion.

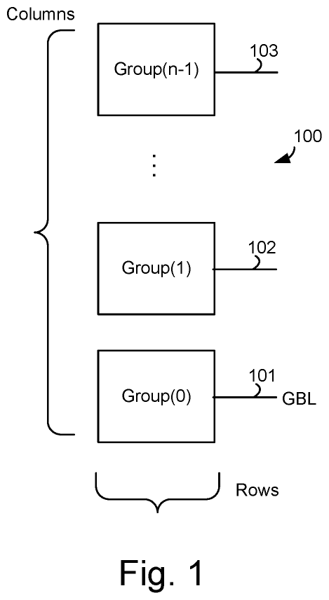

FIG. 1 depicts an example arrangement of groups of cells in a memory device 100, in accordance with various embodiments. The memory device 100 includes a number n groups of memory cells, e.g., Group(0), Group(1), Group(n-1). Each group can include memory cells arranged in rows and columns of an array. In one approach, one memory cell in each group is read at a given time so that n memory cells are read concurrently, one from each group. Each group of memory cells may be coupled to a global bit line (GBL) 101, 102, . . . , 103 which is part of a sense circuit.

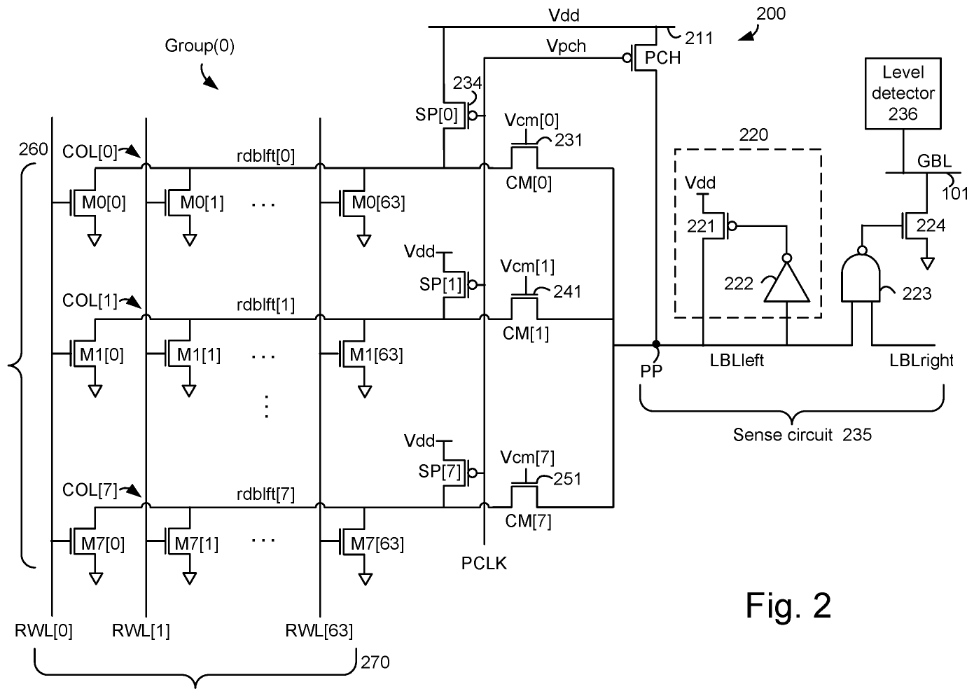

FIG. 2 depicts an example circuit diagram for one of the groups of cells of FIG. 1, where a footer transistor is not used, as a first comparative example, in accordance with various embodiments. The circuit 200 includes the group of memory cells, Group(0), in a memory array, and a sense circuit 235. The group includes a set of columns 260 of memory cells. In particular, eight columns COL[0]-COL[7] of memory cells are depicted as an example only. Additionally, the memory cells are arranged in a set of sixty-four rows 270, again as an example only. Each row is associated with a word line, RWL[0]-RWL[63]. The memory cells in COL[0] include M0[0]-M0[63], which are coupled to a bit line rdblft[0], the memory cells in COL[1] include M1[0]-M1[63], which are coupled to a bit line rdblft[1], . . . , and the memory cells in COL[7] include M7[0]-M7[63], which are coupled to a bit line rdblft[7]. Furthermore, RWL[0] is coupled to memory cells M0[0], M1 [0], . . . , M7 [0], RWL[1] is coupled to memory cells M0[1], M1[1], . . . , M7 [1], and RWL[63] is coupled to memory cells M0[63], M1[63], . . . , M7[63]. Drain sides of the memory cells of each column are coupled to a respective bit line and source sides of the memory cells are individually connected to ground, as indicated by the inverted triangles.

Each respective bit line rdblft[0]-rdblft[7] is also coupled to a respective column select transistor CM[0]-CM[7]. In an example implementation, the column select transistor is an nMOSFET (n-type metal-oxide-semiconductor field effect transistor).

Each column select transistor CM[0]-CM[7] has a control gate coupled to a control gate voltage Vcm[0]-Vcm[7], respectively. For example, Vcm[0] is coupled to the control gate 231 of CM[0], Vcm[1] is coupled to the control gate 241 of CM[1] and Vcm[7] is coupled to the control gate 251 of CM[7].

The bit lines and column select transistors are in turn coupled to a common primary pre-charge node PP at a left-side local bit line (LBLleft). LBLleft and a right-side local bit line (LBLright) are coupled to a NAND gate 223 which in turn is coupled to the control gate of a transistor 224. The transistor 224 has a drain coupled to a global bit line (GBL) and a source coupled to ground. LBLleft is also coupled to a keeper circuit 220. The keeper circuit includes a pMOS transistor 221 and an inverter 222. An output of the inverter is coupled to a control gate of the pMOS transistor 221. A source of the pMOS transistor is coupled to the power supply voltage Vdd and a drain of the pMOS transistor is coupled to the PP node.

During a pre-charge phase of a read operation, the selected bit line and the PP node are charged to a high level, and during an evaluation or sensing phase of the read operation, the selected bit line and the PP node are allowed to discharge to a low level or remain charged at a high level depending on the data state of the selected memory cell, which can act as a pulldown device if it is in a strongly conductive or turned on state. The keeper circuit assists in keeping the node charged high if it is supposed to evaluate to high. Therefore, the keeper circuit should be strong enough to resist noise, leakage, etc. that would otherwise cause the node to errantly discharge to a low value. At the same time, however, the keeper circuit should not be too strong that prevents the node from quickly discharging when it is supposed to discharge.

In this example configuration, the memory cells are ROM cells which include a control gate coupled to a respective word line, a drain coupled to a respective bit line and a source coupled to ground. Each memory cell can store a bit of data, e.g., a 0 or 1 state, in one approach. In one state, the cell allows current to easily flow from the bit line to ground. In the other state, the cell does not allow current to flow from the bit line to ground, expect for a leakage current. The state of a selected memory cell can be determined in a read operation by pre-charging the associated bit line while the word line voltage is low, then raising the word line voltage and sensing an amount of discharge, or voltage, of the bit line.

For example, LBLright can be set at a 1 level so that the output of the NAND gate is 0 only if LBLleft is also at a 1 level. The output of the NAND gate turns on the transistor in this case to ground the voltage of a global bit line, GBL. This grounding can be detected by a level detector 236. If LBLleft is at a 0 level, the output of the NAND gate is at a 1 level. The output of the NAND gate keeps the transistor off in this case.

A primary pre-charge transistor PCH can be coupled to a power supply voltage Vdd at a power supply node 211. The primary pre-charge transistor can be a pMOS transistor having a control gate coupled to a voltage Vpch, provided by a clock signal PCLK. When Vpch is sufficiently low, e.g., at 0 V, the PCH transistor acts as a pass gate to pass Vdd to the PP node. To pre-charge a selected bit line in a read operation, a control gate signal is applied to the corresponding column select transistor to allow the bit line to communicate with the PP node. The corresponding word line voltage is low at this time so that the memory cell cannot act as a pulldown regardless of its data state. Once the pre-charge occurs, the voltage of the selected word is elevated so that the memory cell may or may not acts as a pulldown based on its data state. The level of the PP node then indicates the state of the memory cell.

Although ROM memory is depicted as an example, the techniques herein are applicable to other types of memory including domino-based memory as well as any kind of domino logic level gate. Domino logic is a CMOS-based evolution of the dynamic logic techniques based on either pMOS or nMOS transistors. In general, domino logic is a circuit design technique that makes use of dynamic circuits, and has the advantage of low propagation delay and smaller area due to fewer transistors. In domino logic, dynamic nodes are pre-charged during a portion of a clock cycle and conditionally discharged during another portion of the clock cycle, where the discharging performs the logic function.

Additionally, secondary pre-charge transistors are coupled to the bit lines rdblft[0]-rdblft[63]. In particular, each respective bit line may be coupled to a respective secondary pre-charge transistor. For example, rdblft[0], rdblft[1] and rdblft[7] are coupled to secondary pre-charge transistors SP[0], SP[1] and SP[7], respectively. Each secondary pre-charge transistor may be a p-type MOSFET (pMOS), for example, having a source coupled to the power supply node 211 and a drain coupled to the bit line. Further, the control gate of each secondary pre-charge transistor is coupled to PCLK. For example, SP[0] has a control gate 234.

The secondary pre-charge transistors have a role in maintaining the pre-charge of the respective bit line, in addition to the role of the primary pre-charge transistor.

One technique to improve array leakage for a Read only Memory (ROM) or Register File (RF) involves using a footer device. A footer device can be a transistor which is arranged to ground the memory cells. A footer device improves active and ideal leakage, but it does not improve Vmin during a Read-0 operation where it checks local bit line (LBL) noise sensitivity. Vmin refers to the minimum voltage a circuit needs to operate properly. It is expected that, during a Read-0 operation, the rdblft node should hold a high value with optimum keeper strength such that the Vmin performance should not degrade much in a Read-1 operation. Moreover, there is always a leakage-driven constraint on the maximum supporting number of bits per LBL. A main goal is to reduce leakage such that a larger number of bits per LBL can be supported to achieve a better Vmin for a denser memory array or compiler.

Supporting a larger number of bits per LBL is problematic with a column mux (CM) based design. For example, consider this problem for 64 bits (memory cells) per LBL with a CM=8 (eight column) ROM design. A first comparative read path circuit is depicted in FIG. 2. There are a total of eight column mux devices (column select transistors) which are controlled by eight different column select signals, Vcm[7:0]. In an active read operation, one column select transistor among the eight will turn on (enter a conductive state). There are eight secondary bit lines (rdbllft[7:0]), also referred to as rdblft[7:0], and, for each bit line, there will be one secondary dedicated pre-charge transistor to pre-charge the rdbllft[7:0] nodes when the CM devices are turned off. LBL1 ft is the primary LBL node with a dedicated keeper and primary pre-charge device. To improve performance, the column select transistors should have a relatively low threshold voltage (Vth) in comparison to the Vth of the memory cells, which have a medium Vth.

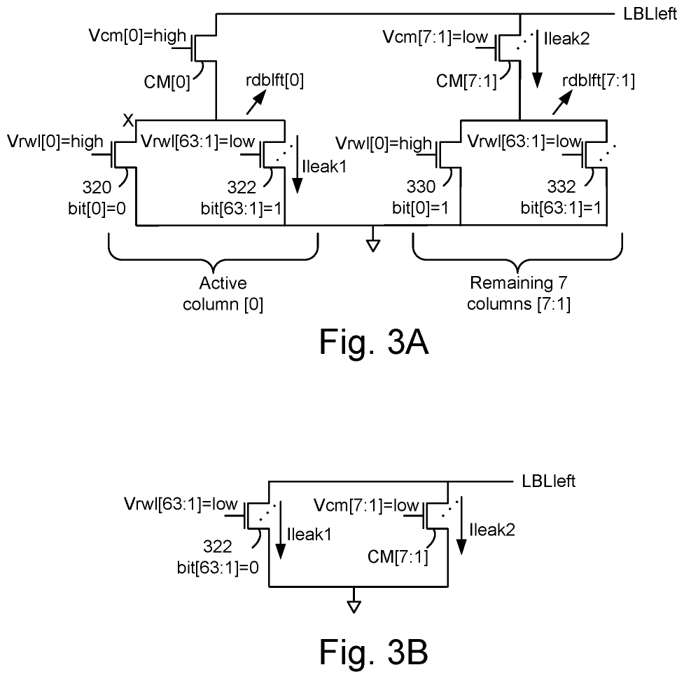

FIG. 3A depicts a current leakage model for the circuit of FIG. 2 in a Read-0 operation, in accordance with various embodiments. Read operations can include Read-0 (R0) and Read-1 (R1). Read-0 is a read operation for a memory cell which has a bit value of 1 (a low data state) and provides a strong, direct discharge path for a bit line, and Read-1 is a read operation for a memory cell which has a bit value of 0 (a high data state) and provides only a leakage path for a bit line. Specifically, with Read-1, the local bit-line (BL or rdblft) holds a high value. In this example, it is a domino path, where the domino path is followed by an inverter (CMOS logic) so an inversion is performed, resulting in a low or 0 value. In this case, all bit cells will leak, as their gate voltage is 0 V. With Read-0, the local bit-line discharges from a LBL high value to a low value. Again, with a domino path, inverter logic will be used, resulting in a high value. In this case, among the 64 bit cells connected to the bit line, one bit-cell gate voltage will be high and the LBL node will discharge through that transistor.

The model is for a worst case leakage condition. In this case, one out of 64 read word lines (RWLs) and one out of 8 CM signals will be high in active read mode. The active or selected column has the column select transistor CM[0] while the inactive or unselected columns have the column select transistors CM[7:1], represented by a transistor 310. The active or selected word line is RWL[0] while the inactive or unselected word lines are RWL[63:1].

In the active column, CM[0] receives a high or turn on signal Vcm[0]. The active column further includes the transistor 320 in parallel with the transistor 322. The transistor 320 represents a selected memory cell, bit[0]=0, which receives a high or turn on voltage Vrwl[0] on its control gate. RWL[0] is the selected word line in this example. The transistor 322 represents the unselected memory cells, bit[63:1]=1, which receive a low or turn off voltage Vrwl[63:1] on their control gates. For the memory cells denoted by bit[63:1]=1, a conductive path through the memory cells connects the bit line to ground, resulting in a leakage current, Ileak1. The cells with a bit value of 0 or 1 are referred to as rombit0 or rombit1, respectively. The “X” indicates no current leakage.

In the remaining seven columns, which are the inactive columns, CM[7:1] receive a low or turn off signal, Vcm[7:1]. CM[7:1] denotes the transistors CM[7] through CM[1]. A conductive path through these column select transistors results in a leakage current, Ileak2. These columns further include a transistor 330 in parallel with a transistor 332. The transistor 330 represents an unselected memory cell, bit[0]=1, connected to the selected word line RWL[0], which receives a high or turn on voltage, Vrwl[0], on its control gate. The transistor 332 represents the unselected memory cells, bit[63:1]=1, which receive a low or turn off voltage, Vrwl [63:1], on their control gates.

An equivalent leakage model for the Read-0 operation is depicted in FIG. 3B.

FIG. 3B depicts an equivalent of the current leakage model of FIG. 3A, in accordance with various embodiments. The circuit includes, in parallel, the transistor 322 with the associated leakage current Ileak1 and CM[7:1] with the associated leakage current Ileak2.

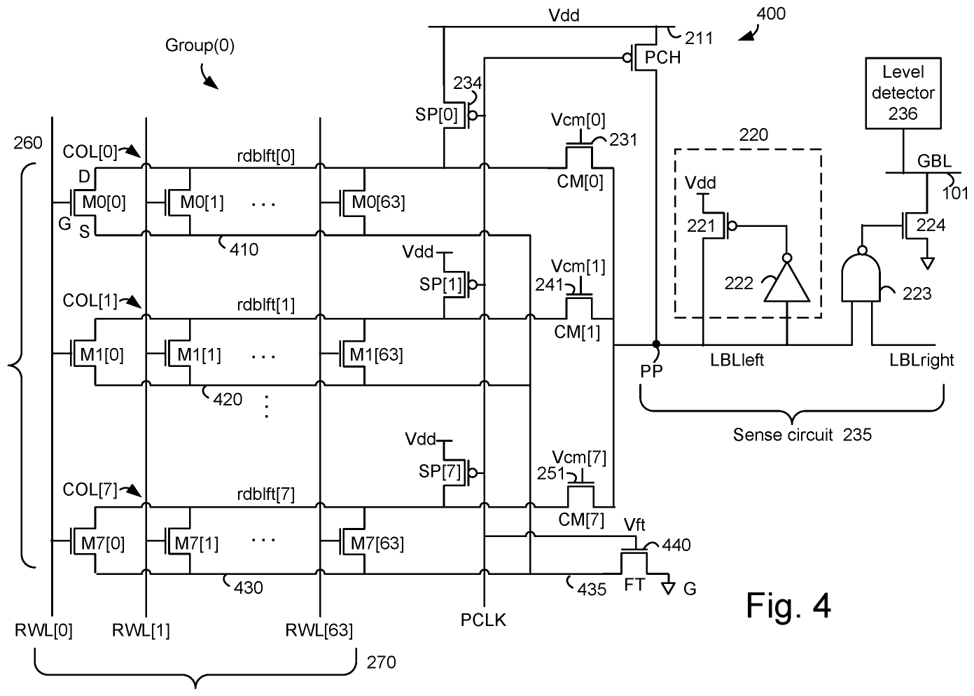

FIG. 4 depicts an example circuit diagram for one of the groups of cells of FIG. 1, where a common footer transistor is used, as a second comparative example, in accordance with various embodiments. The circuit 400 is the same as the circuit 200 of FIG. 2 except for the addition of paths 410, 420 and 430 and a footer transistor (FT) or other switch. Specifically, for each column, each memory cell has its source side coupled to a conductive path for the column, where the different conductive paths are combined at a node 435. For example, paths 410, 420 and 430 are provided in COL[0], COL[1] and COL[7], respectively. The source (S), drain (D) and control gate (G) of the memory cell M0 [0] are depicted as an example, where the source is coupled to the path 410.

The footer transistor has a control gate 440 which can receive PCLK as its control voltage (Vft) for turn on or turn off. When the footer transistor is turned on, the node 435 is coupled to ground (G) or other reference voltage. When the footer transistor is turned off, the node 435 is decoupled from ground or other reference voltage so that the voltages on the paths are floating.

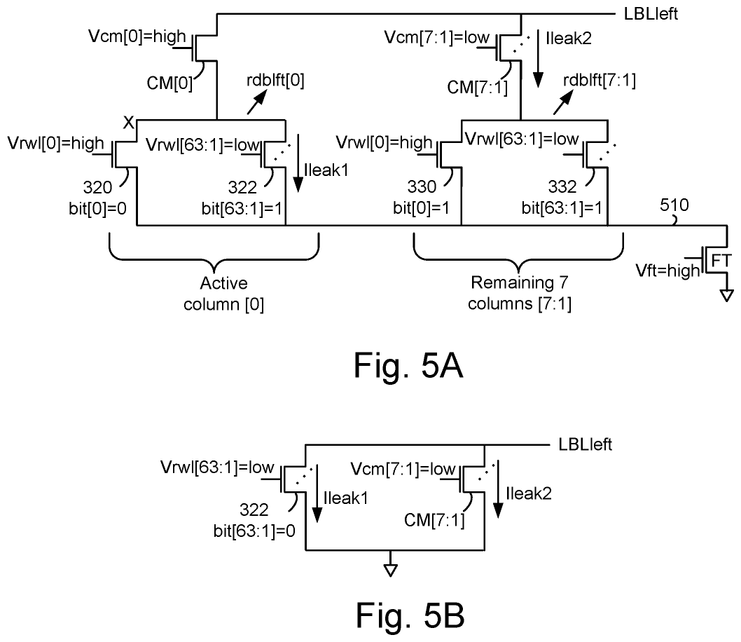

A common footer transistor can be used in a memory array for leakage power savings. However, the common footer does not help reduce active leakage during a Read-0 operation. This can be understood further in view of the current leakage model of FIG. 5A and the corresponding equivalent model of FIG. 5B. The equivalent leakage model is the same for both with and without a common footer, so it is clear that there is no active leakage advantage during a Read-0 operation.

FIG. 5A depicts a current leakage model for the circuit of FIG. 4, in accordance with various embodiments. The model is the same as in FIG. 3A except for the addition of the footer transistor FT to ground the path 510 when PCLK is high, assuming FT is an nMOS. An equivalent leakage model is depicted in FIG. 5B.

FIG. 5B depicts an equivalent of the current leakage model of FIG. 5A, in accordance with various embodiments. This is the same as FIG. 3B. The circuit includes, in parallel, the transistor 322 with the associated leakage current Ileak1 and CM[7:1] with the associated leakage current Ileak2.

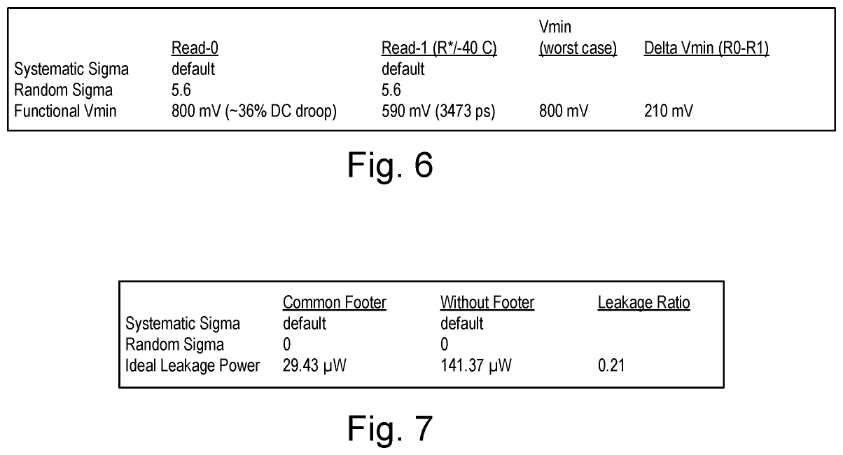

FIG. 6 depicts a table indicating a functional Vmin summary for both the circuits of FIG. 3 with no footer transistor and FIG. 4 with a common footer transistor, in accordance with various embodiments. A goal is to reduce Vmin, the minimum voltage a circuit needs to operate properly. A comparison is made between Read-0 and Read-1 operations. For a Read-0 operation, the systematic sigma is a default, the random sigma is 5.6 and the functional Vmin is 800 mV, at a 36% direct current (DC) droop. For a Read-1 operation, the systematic sigma is a default, the random sigma is 5.6 and the functional Vmin is 590 mV, at a time of 3473 picoseconds (ps). The Read-1 operation is for different process skews (denoted by R*) and a temperature of −40 C. The worst case Vmin, which is highest Vmin of Read-0 and Read-1, is 800 mV. The Delta Vmin, which is the Vmin for Read-0 (R0) minus the Vmin for Read-1 (R1), is 800−590=210 mV.

Thus, with both a common footer and without a footer, significant degradation was observed in Vmin in a Read-0 operation. In particular, an increase of 210 mV was observed. This is a significant increase and is a main problem in designing a read path with a common footer transistor.

FIG. 7 depicts a table indicating an ideal leakage power comparison, comparing the circuit of FIG. 2 with no footer transistor to the circuit of FIG. 4 with a common footer transistor, in accordance with various embodiments. Ideal leakage power saving, which is 79% in this example, creates a significant degradation (increase) in functional Vmin in the read path. This implies a performance loss when a larger number of bits per LBL are supported in a column mux-based design. For improved performance, the CM and FT devices should be low-Vth devices, but this will create an issue with Vmin due to the Vmin limitation during Read-0. If medium-Vth devices are used for CM and FT, that will slow down the performance path for Read-1 operations.

The data is obtained at a process skew of TTTT, a supply voltage of 0.85 V and a temperature of 100 C. For the common footer design, the systematic sigma is a default, the random sigma is 0 and the ideal leakage power is 29.43 μW. For the design without a footer, the systematic sigma is a default, the random sigma is 0 and the ideal leakage power is 141.37 μW. The leakage ratio is therefore 29.43/141.37=0.21.

Various solutions can address the increase in Vmin but each solution has its own drawbacks. In a first solution, to improve Read-0 Vmin, the keeper circuit 220 can be made much stronger but that will degrade Read-1 Vmin further. This in turn degrades performance due to an increased contention between the keeper and the read pull down. A second solution involves supporting a reduced number of bits, e.g., 32 bits per LBL instead of 64 bits. This improves performance, but there is a degradation in area and power, thereby degrading the Power-Performance-Area (PPA) metric. A third solution is to reduce the number of columns, e.g., CM=4 instead of 8. This improves performance but, again, area and power are impacted. A fourth solution is to change the device type. This may help in the Read-0 operation, but again it will create an issue in the Read-1 discharge path and it will cause a further slowdown.

With the second solution, there will be an area overhead cost of around 16% if we need to resolve this issue by considering 32 bits/LBL. A similar area impact will be seen with the third solution.

Moreover, leakage power can be saved by about 80-90% with a common footer device at EBB level which is significant. EBB is an embeddable building block, which is a memory instance. With the first solution, there will be a Vmin impact of around 60-80 mV.

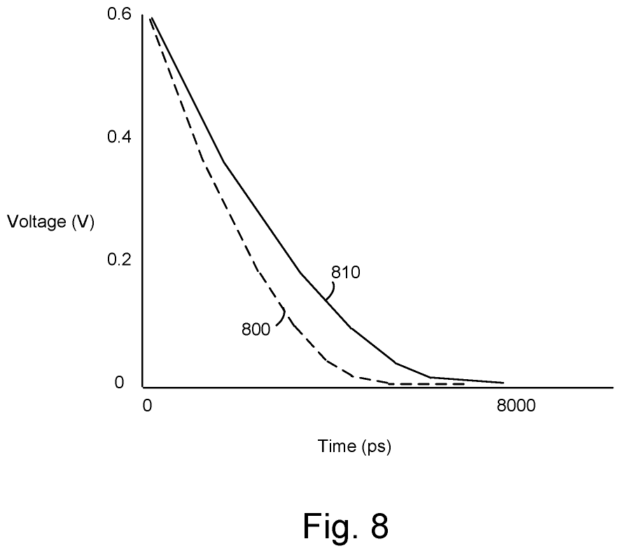

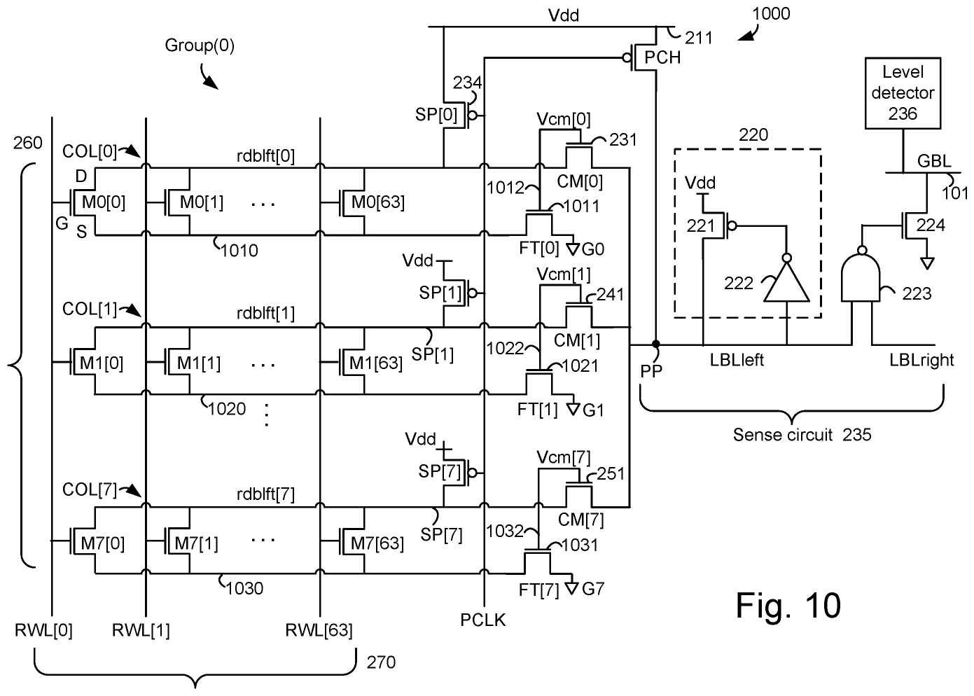

FIG. 8 depicts plots of voltage versus time, indicating a leakage path discharge time in a Read-0 operation, comparing the circuit of FIG. 4 with a common footer transistor (plot 800) with the circuit of FIG. 10 with a separate respective footer transistor for each column (plot 810), e.g., a split footer, in accordance with various embodiments. The data is zero-sigma data obtained at a process skew of RFFF, a supply voltage of 0.65 V and a temperature of 125 C. The time varies from 0-8000 ps and the voltage varies from 0-0.6 V.

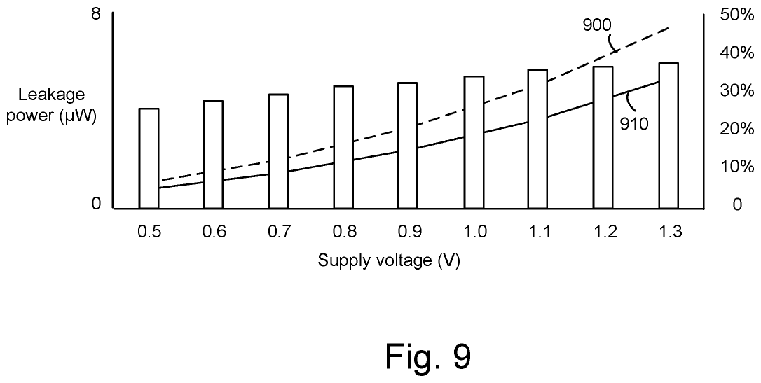

The split footer design provides a footer transistor for each column instead of single footer for all columns of the array, e.g., all eight columns in FIG. 4. This reduces active leakage in a Read-0 operation. Each footer device is dedicated to a single respective column and controlled by a respective dedicated column select signal. This ensures that only one footer transistor at a time will be turned on while the remaining footer transistors are turned off. This type of footer concept is named as a split footer. This splitting concept helps to reduce leakage current by about compared to the common footer. This improvement is depicted in FIGS. 8 and 9. In FIG. 8, the rate of decrease of the voltage over time represents the amount of current leakage. A slower rate of decrease, as seen with the plot 810, represents a reduced amount of current leakage.

FIG. 9 depicts plots of leakage power versus time, and percent improvement in leakage power versus time, comparing the circuit of FIG. 4 with a common footer transistor (plot 900) to the circuit of FIG. 10 with a separate respective footer transistor for each column (plot 910), in accordance with various embodiments. The leakage power is depicted at the left-hand vertical axis and corresponds to the plots 910 and 900 and the percent improvement is depicted at the right-hand vertical axis and corresponds to the bar chart. The supply voltage varies from 0.5-1.3 V, the leakage power varies from 0-8 μW and the percent improvement varies from 0-50%.

The plots show that leakage power is advantageously decreased by larger percentages as the supply voltage increases. For example, at 0.5 V the decrease is 25% and at 1.3 V the decrease is 37%.

FIG. 10 depicts an example circuit diagram for one of the groups of cells of FIG. 1, where a separate respective footer transistor is used for each column, e.g., a split footer, in accordance with various embodiments. The circuit 1000 is similar to that of FIG. 4 but includes a separate, independently controlled footer transistor for each column. For example, the memory cells of COL[0], COL[1] and COL[7] and coupled via paths 1010, 1020 and 1030, respectively, to the drain sides of footer transistors FT[0], FT[1] and FT[7], respectively. The paths 1010, 1020 and 1030 are also referred to as ROM Vss paths because they connect the ROM memory cells to a ground or Vss=0 V path.

The source sides of FT[0], FT[1] and FT[7], in turn, are coupled to respective ground points G0, G1 and G7, respectively, which can be separate or coupled to one another. Additionally, the control gates 1011, 1021 and 1031 of FT[0], FT[1] and FT[7], respectively, are coupled to the control gates of CM[0], CM[1] and CM[7], respectively, by paths 1012, 1022 and 1032, respectively. As a result, in each column, the control signal which is used to turn on and off the column select transistor, e.g., Vcm[0], Vcm[1] and Vcm[7], can also be used to turn on and off the footer transistor. Optionally, the control gate of the footer transistor is not coupled to the control gate of the column select transistor but the two transistors receive the same control signal via different independent paths.

In either case, the respective footer transistors of the columns are independently controllable (independent of one another), in one approach. Each respective footer transistor is controllable via a voltage on a respective control path, e.g., paths 1012, 1022 or 1032.

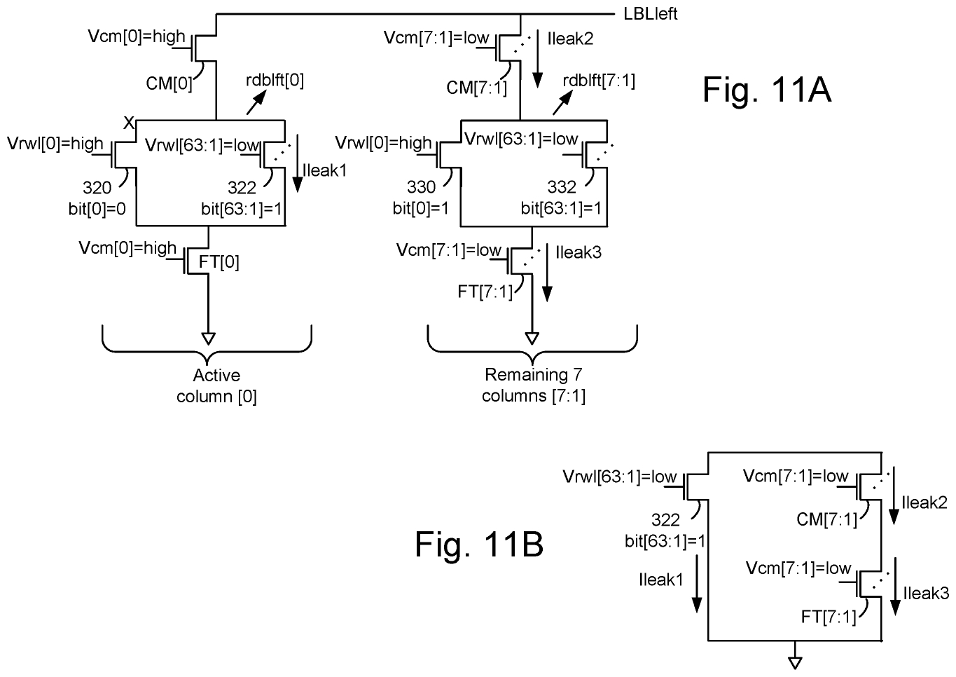

The split footer concept can be used, e.g., in a domino-based read path to resolve the Read-0 Vmin issue and thereby support an increased number of bits per LBL/column. Rather than using a single footer device with large device size, as in FIG. 4, the footer is distributed based on column mux signals. A dedicated footer device can be used for each column. Further, the footer device can be controlled with same column select signals, e.g., Vcm [7:0]. The footer device will leak only through the active column and the leakage contribution from the remaining columns will be negligible due to the stacking effect of the nMOS transistors. An actual leakage model for the active Read-0 operation is shown in FIG. 11A and an equivalent leakage model is shown in FIG. 11B.

The CM transistors and FT transistors may both be nMOS transistors (with an n-type polarity), as depicted, or both be pMOS transistors (with a p-type polarity). Generally, in a column, each respective column select transistor and each respective footer transistor have a same polarity. The CM transistors and FT transistors could be other types of transistors or switches as well.

The design of FIG. 10 provides a number of advantages. For example, it reduces active leakage significantly at the time of a Read-0 operation and that will allow supporting of a larger number of bits per LBL. This, in turn, can improve the density of a high-density ROM/RF compiler.

The footer device automatically helps to reduce the ideal leakage power. A first benefit is improving ideal leakage power, as a default feature of the footer device. At the same time, the footer improves active leakage power in Read-0 operations and that improves the functional Vmin.

This solution provided is better than a common footer design since the contribution of parasitic factors at the ROM Vss node is reduced, resulting in a faster discharge in the Read-1 operation. It also provides better performance at higher voltages.

The design can be used to provide a low leakage, high-density compiler with moderate frequency, without creating any extra complexity in design.

Finally, the same solution can be used for any domino-based read operations. Thus, both RF/ROM can benefit.

FIG. 11A depicts a current leakage model for the circuit of FIG. 10, in accordance with various embodiments. In the active column, CM[0] receives a high or turn on signal, Vcm[0]=high. The active column further includes the transistor 320 in parallel with the transistor 322. The transistor 320 represents a selected memory cell, bit[0]=0, which receives a high or turn on voltage Vrwl[0]=high on its control gate. The transistor 322 represents the unselected memory cells, bit[63:1]=1, which receive a low or turn off voltage Vrwl[63:1]=low on their control gates. For the memory cells denoted by bit[63:1]=1, a conductive path through the memory cells connects the bit line to ground, resulting in a leakage current, Ileak1.

The footer transistor FT[0] is connected in series with the parallel transistors 320 and 322 and the transistor CM[0]. FT[0] receives the high, turn on voltage Vcm[0], assuming CM[0] is the selected column in the read operation.

In the remaining seven columns, which are the inactive columns, CM[7:1] receives a low or turn off signal Vcm[7:1]=low. A conductive path through these column select transistors results in a leakage current, Ileak2. These columns further include the transistor 330 in parallel with the transistor 332. The transistor 330 represents an unselected memory cell, bit[0]=1, connected to the selected word line RWL[0], which receives a high or turn on voltage Vrwl[0]=high on its control gate. The transistor 332 represents the unselected memory cells, bit[63:1]=1, which receive a low or turn off voltage Vrwl[63:1]=low on their control gates.

For each remaining column, the footer transistors FT[7:1] are connected in series with the parallel transistors 330 and 332 and the transistors CM[7:1]. FT[7:1] receive the low, turn off voltage Vcm[7:1]=low, resulting in a leakage current, Ileak3.

An equivalent leakage model for the Read-0 operated is depicted in FIG. 3B.

FIG. 11B depicts an equivalent of the current leakage model of FIG. 11A, in accordance with various embodiments. CM[7:1] and FT[7:1] are in series with one another, and together they are parallel with the transistor 322. The left hand branch of the circuit therefore includes Ileak1 and the right hand branch includes Ileak2 and Ileak3.

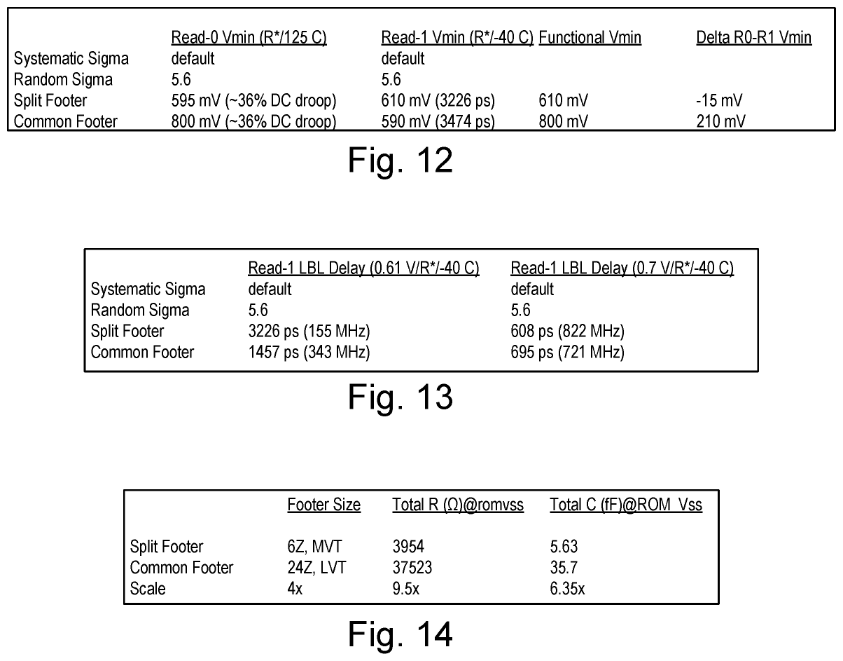

FIG. 12 depicts a table indicating a Vmin, comparing the circuit of FIG. 4 with a common footer transistor to the circuit of FIG. 10 with a separate respective footer transistor for each column, in accordance with various embodiments. A comparison is made between Read-0 and Read-1 operations. For a Read-0 operation, the systematic sigma is a default and the random sigma is 5.6. For a split footer design, Vmin is 595 mV and, for a common footer design, Vmin is 800 mV, both measured at a 36% DC droop. The Read-0 operation is for different process skews (denoted by R*) and a temperature of 125 C. For a Read-1 operation, the systematic sigma is a default and the random sigma is 5.6. For a split footer design, Vmin is 610 mV, measured at 3226 ps, and for a common footer design, Vmin is 590 mV, measured at 3474 ps. The Read-1 operation is for different process skews (denoted by R*) and a temperature of −40 C.

The worst case functional Vmin is 610 mV or 800 mV for the split footer or common footer, respectively. The Delta R0-R1 Vmin is therefore 595−610=−15 mV or 800−590=210 mV for the split footer or common footer, respectively. The −15 mV delta is negligible.

The Vmin advantage with the split footer design is significant. It is clear that active leakage in Read-0 improves significantly and, as a result, a 205 mV Vmin delta is observed in Read-0 when comparing the common footer and split footer designs. There is little Vmin impact in Read-1 with the split footer design because the footer device is smaller, e.g., four times smaller, compared to the common footer (see FIG. 14), so that its impact on Vmin is about 20 mV. Overall, a much better functional Vmin can be achieved with proposed design. In particular, a 190 mV Vmin advantage can be achieved, as an example.

FIG. 13 depicts a table indicating performance, comparing the circuit of FIG. 4 with a common footer transistor to the circuit of FIG. 10 with a separate respective footer transistor for each column, in accordance with various embodiments. A comparison is made between supply voltages of 0.61 V and 0.7 V in a Read-1 operation. For a Read-1 operation with a supply voltage of 0.61 V, different process skews (denoted by R*) and a temperature of −40 C, the systematic sigma is a default and the random sigma is 5.6. The LBL delay is 3226 ps at 155 MHz or 1457 ps at 343 MHz for the split footer or common footer, respectively. For a Read-1 operation with a supply voltage of 0.7 V, different process skews (denoted by R*) and a temperature of −40 C, the systematic sigma is a default and the random sigma is 5.6. The LBL delay is 608 ps at 822 MHz or 695 ps at 721 MHz for the split footer or common footer, respectively.

FIG. 14 depicts a table indicating a footer device size, resistance (R) and capacitance (C), comparing the circuit of FIG. 4 with a common footer transistor to the circuit of FIG. 10 with a separate respective footer transistor for each column, in accordance with various embodiments. The footer transistor size is 6Z, MVT for a split footer and 24Z, LVT for a common footer, at a scale of 4×. Z denotes the number of fins in the transistor. MVT denotes medium Vth. LVT denotes low Vth. The total resistance R in Ohms at ROM Vss is 3954 for the split footer and 37523 for the common footer, at a scale of 9.5×. The total capacitance (C) in femto Farads (fF) is 5.63 for the split footer and 35.7 for the common footer at a sale of 6.35×.

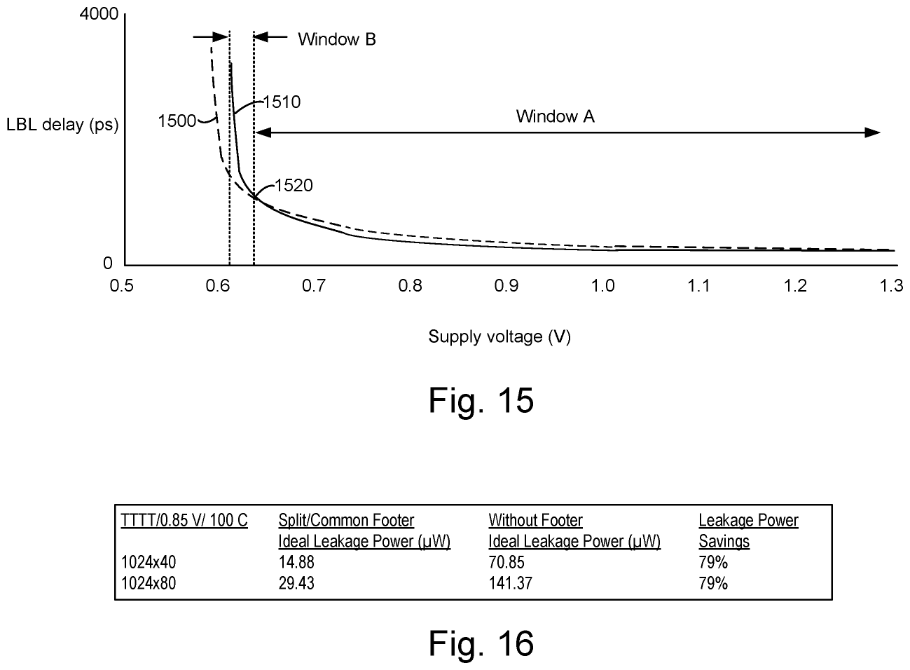

FIG. 15 depicts plots of an LBL bit line delay versus supply voltage, comparing the circuit of FIG. 4 with a common footer transistor (plot 1500) to the circuit of FIG. 10 with a separate respective footer transistor for each column (plot 1510), in accordance with various embodiments. The horizontal axis depicts supply voltage, which varies from 0.5-1.3 V and the vertical axis depicts LBL delay in ps, which varies from 0-4000. There is a crossover point 1520 between the plots at 0.64 V. It shows a dual performance trend that creates two windows. A faster LBL delay is observed for the split footer design in Window A due to a smaller interconnect parasitic which is observed for the ROM Vss node. For the common footer, all 8 ROM Vss are shorted and that causes 9.5×and 6.35×more total R and C respectively, as depicted in FIG. 14. Window B is contention limited, as discussed above in connection with FIG. 7. The split footer design shows a 4-15% better performance for voltages greater than 0.64 V due mainly to improvements in R and C when moving from the common footer design to the split footer design.

FIG. 16 depicts a table indicating a current leakage advantage, comparing the case of common footer transistor or split footer transistor as in FIG. 4 or 10, respectively, to the case with no footer transistor as in FIG. 2, in accordance with various embodiments. The data is obtained at a process skew of TTTT, a supply voltage of 0.85 V and a temperature of 100 C. For the split or common footer design, the ideal leakage power in μW is 14.88 or 29.43 for a 1024×40 or a 1024×80 memory array size, respectively, referring to the number of rows×number of columns. Without a footer transistor, the ideal leakage power in μW is 70.85 or 141.37 for a 1024×40 or a 1024×80 memory array size, respectively. The savings in leakage power is a significant 79%.

The split footer design resolves the Vmin limitation and improves PPA in a low power design.

Generally, the design can be used in a column mux-based and domino-based memory design to address the read Vmin issue for Read-0 operations. Advantageously, no additional control signal is needed to control the split footer transistors. Instead, the existing column select control signals can be reused. The loading of the column select driver will increase, but that will not grow the area as long as device loading is smaller than the RWL driver device loading. There will be some dynamic power impact due to the extra loading. But, at the same time, it will improve pre-charge clock loading compared to the common footer design. Hence, the dynamic power impact is nullified.

By restricting the overall split footer size so that it is not greater than the common footer size, there will be no area penalty. Moreover, per column, there will be a single dedicated footer transistor that will reduce interconnect load for intermediate net ROM Vss. This will help to improve performance compared to the common footer design.

With this proposed topology, density (area) is improved as a larger number of bits per LBL can be supported and optimal leakage power can be achieved with some performance impact due to extra stacking of the footer devices.

If the design Vmin is limited by Read-0 and there is large difference between Read-0 and Read-1 Vmin, then this topology can help to balance the Vmin.

The topology reduces ideal leakage by 79%, and improves Vmin by 190 mV, which is significant. Moreover, a 4-15% performance improvement is achieved for voltages greater than 0.64 V in the example implementation.

If dedicated metal tracks are not available for each column of ROM Vss, ROM Vss can be shared with multiple columns, e.g., two or four columns. In that case, a partial active leakage benefit can be achieved. With the same concept, it will achieve a much better Vmin compared to the common footer design. For example, the design of FIG. 10 could be modified to include a number N of footer transistors for a number M of columns, where N<M. For example, one footer transistor could be provided for every two columns of memory cells, e.g., four footer transistors for an array with eight columns. This reduces the number of control signals need to turn on and off the footer transistors, and the number of ground paths, while still providing improvements in leakage current compared to the design of FIG. 4.

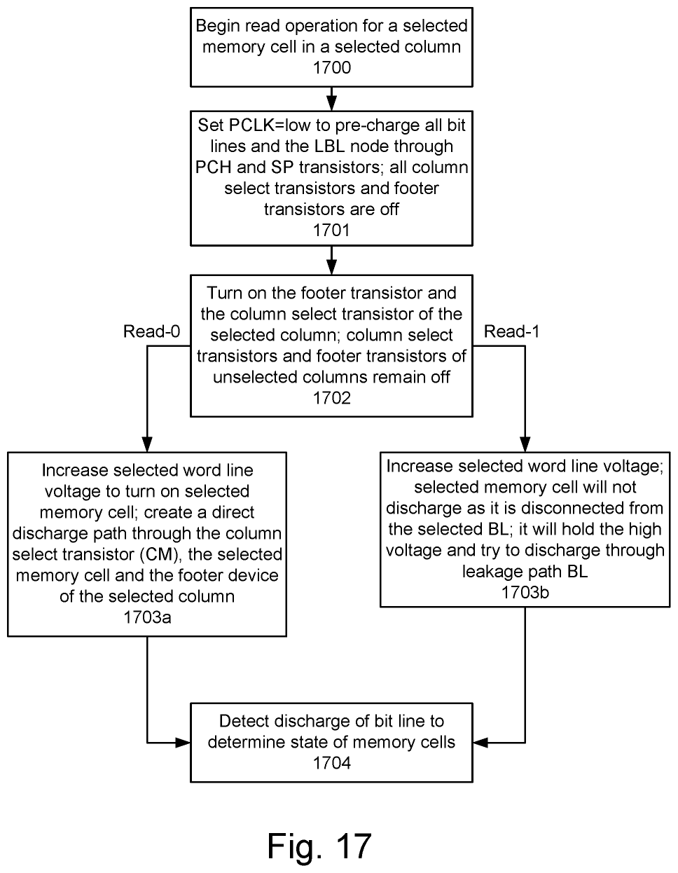

FIG. 17 depicts a flowchart of an example method for performing a read operation in the circuit of FIG. 10, in accordance with various embodiments. Step 1700 begins a read operation for a selected memory cell. This is a cell in a selected column, coupled to a selected word line and a selected bit line. For example, referring to FIG. 10, assume COL[0] and memory cell M0 [0] are selected. Step 1701 includes setting PCLK=low to pre-charge all bit lines and the LBL node through the PCH and SP transistors. Additionally, all column select transistors and footer transistors are kept off. Step 1702 includes turning on the footer transistor, e.g., FT[0] and the column select transistor, e.g., CM[0], of the selected column. The column select transistors CM[7:1] and footer transistors FT[7:1] of the unselected columns remain off.

If the read operation is a Read-0 operation (a first read operation), step 1703a is performed. This step includes increasing the selected word line voltage to turn on the selected memory cell, thus creating a direct discharge path through the column select transistor CM[0], the selected memory cell and the footer device FT[0] of the selected column.

If the read operation is a Read-1 operation (a second read operation), step 1703b is performed. This step includes increasing the selected word line voltage, such that the selected memory cell will not discharge as it is disconnected from the selected BL. Instead, the selected memory cell will hold the high voltage and try to discharge through a leakage path BL. The split footer design therefore reduces leakage in a Read-1 operation to achieve a better Vmin.

Subsequently, step 1704 includes detecting the discharge of the bit line to determine a state of the memory cell.

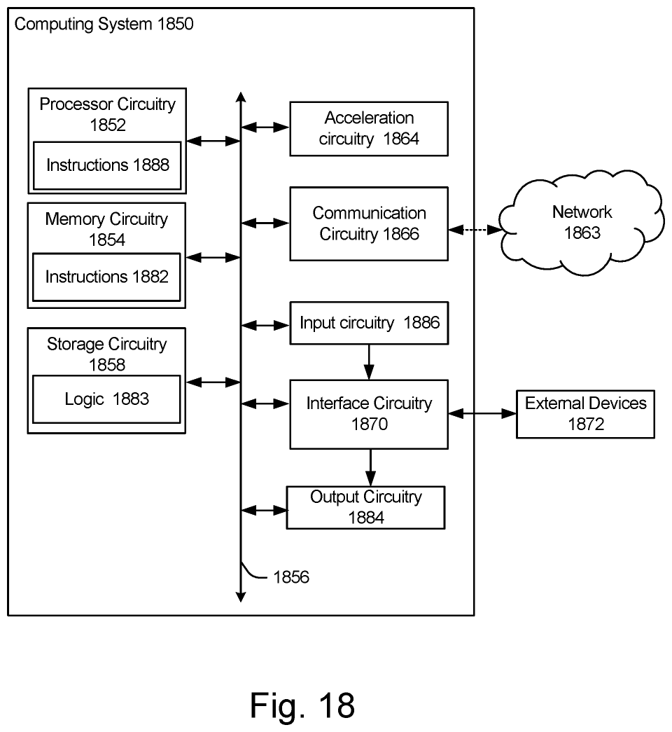

FIG. 18 illustrates an example of components that may be present in a computing system 1850 for implementing the techniques (e.g., operations, processes, methods, and methodologies) described herein. The memory circuitry 1854 may store instructions and the processor circuitry 1852 may execute the instructions to perform the functions described herein including the process of FIG. 17. The memory circuitry 1854 may correspond to the memory array Group(0) of FIG. 10.

The computing system 1850 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 1850, or as components otherwise incorporated within a chassis of a larger system. For one embodiment, at least one processor 1852 may be packaged together with computational logic 1882 and configured to practice aspects of various example embodiments described herein to form a System in Package (SiP) or a System on Chip (SoC).

The system 1850 includes processor circuitry in the form of one or more processors 1852. The processor circuitry 1852 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 1852 may include one or more hardware accelerators (e.g., same or similar to acceleration circuitry 1864), which may be microprocessors, programmable processing devices (e.g., FPGA, ASIC, etc.), or the like. The one or more accelerators may include, for example, computer vision and/or deep learning accelerators. In some implementations, the processor circuitry 1852 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 1852 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low voltage processor, an embedded processor, or any other known processing elements, or any suitable combination thereof. The processors (or cores) 1852 may be coupled with or may include memory/storage and may be configured to execute instructions stored in the memory/storage to enable various applications or operating systems to run on the platform 1850. The processors (or cores) 1852 is configured to operate application software to provide a specific service to a user of the platform 1850. In some embodiments, the processor(s) 1852 may be a special-purpose processor(s)/controller(s) configured (or configurable) to operate according to the various embodiments herein.

As examples, the processor(s) 1852 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 1852 may be a part of a system on a chip (SoC), System-in-Package (SiP), a multi-chip package (MCP), and/or the like, in which the processor(s) 1852 and other components are formed into a single integrated circuit, or a single package, such as the Edison™ or Galileo™ SoC boards from Intel® Corporation. Other examples of the processor(s) 1852 are mentioned elsewhere in the present disclosure.

The system 1850 may include or be coupled to acceleration circuitry 1864, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 1864 may comprise logic blocks or logic fabric and other interconnected resources that may be programmed (configured) to perform various functions, such as the procedures, methods, functions, etc. of the various embodiments discussed herein. In such implementations, the acceleration circuitry 1864 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 1852 and/or acceleration circuitry 1864 may include hardware elements specifically tailored for machine learning and/or artificial intelligence (AI) functionality. In these implementations, the processor circuitry 1852 and/or acceleration circuitry 1864 may be, or may include, an AI engine chip that can run many different kinds of AI instruction sets once loaded with the appropriate weightings and training code. Additionally or alternatively, the processor circuitry 1852 and/or acceleration circuitry 1864 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPs™) provided by AlphalCs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 1852 and/or acceleration circuitry 1864 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin 970 provided by Huawei®, and/or the like. In some hardware-based implementations, individual subsystems of system 1850 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 1850 also includes system memory 1854. Any number of memory devices may be used to provide for a given amount of system memory. As examples, the memory 1854 may be, or include, volatile memory such as random access memory (RAM), static RAM (SRAM), dynamic RAM (DRAM), synchronous DRAM (SDRAM), RAIVIBUS® Dynamic Random Access Memory (RDRAM®), and/or any other desired type of volatile memory device. Additionally or alternatively, the memory 1854 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 1854 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 1858 provides persistent storage of information such as data, applications, operating systems and so forth. In an example, the storage 1858 may be implemented via a solid-state disk drive (SSDD) and/or high-speed electrically erasable memory (commonly referred to as “flash memory”). Other devices that may be used for the storage 1858 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 1854 and/or storage circuitry 1858 may also incorporate three-dimensional (3D) cross-point (XPOINT) memories from Intel® and Micron®.

The memory circuitry 1854 and/or storage circuitry 1858 is/are configured to store computational logic 1883 in the form of software, firmware, microcode, or hardware-level instructions to implement the techniques described herein. The computational logic 1883 may be employed to store working copies and/or permanent copies of programming instructions, or data to create the programming instructions, for the operation of various components of system 1850 (e.g., drivers, libraries, application programming interfaces (APIs), etc.), an operating system of system 1850, one or more applications, and/or for carrying out the embodiments discussed herein. The computational logic 1883 may be stored or loaded into memory circuitry 1854 as instructions 1882, or data to create the instructions 1882, which are then accessed for execution by the processor circuitry 1852 to carry out the functions described herein. The processor circuitry 1852 and/or the acceleration circuitry 1864 accesses the memory circuitry 1854 and/or the storage circuitry 1858 over the interconnect (IX) 1856. The instructions 1882 direct the processor circuitry 1852 to perform a specific sequence or flow of actions, for example, as described with respect to flowchart(s) and block diagram(s) of operations and functionality depicted previously. The various elements may be implemented by assembler instructions supported by processor circuitry 1852 or high-level languages that may be compiled into instructions 1888, or data to create the instructions 1888, to be executed by the processor circuitry 1852. The permanent copy of the programming instructions may be placed into persistent storage devices of storage circuitry 1858 in the factory or in the field through, for example, a distribution medium (not shown), through a communication interface (e.g., from a distribution server (not shown)), over-the-air (OTA), or any combination thereof.

The IX 1856 couples the processor 1852 to communication circuitry 1866 for communications with other devices, such as a remote server (not shown) and the like. The communication circuitry 1866 is a hardware element, or collection of hardware elements, used to communicate over one or more networks 1863 and/or with other devices. In one example, communication circuitry 1866 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 1866 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 1856 also couples the processor 1852 to interface circuitry 1870 that is used to connect system 1850 with one or more external devices 1872. The external devices 1872 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 1850, which are referred to as input circuitry 1886 and output circuitry 1884. The input circuitry 1886 and output circuitry 1884 include one or more user interfaces designed to enable user interaction with the platform 1850 and/or peripheral component interfaces designed to enable peripheral component interaction with the platform 1850. Input circuitry 1886 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 1884 may be included to show information or otherwise convey information, such as sensor readings, actuator position(s), or other like information. Data and/or graphics may be displayed on one or more user interface components of the output circuitry 1884. Output circuitry 1884 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 1850. The output circuitry 1884 may also include speakers and/or other audio emitting devices, printer(s), and/or the like. Additionally or alternatively, sensor(s) may be used as the input circuitry 1884 (e.g., an image capture device, motion capture device, or the like) and one or more actuators may be used as the output device circuitry 1884 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 1850 may communicate over the IX 1856. The IX 1856 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 1856 may be a proprietary bus, for example, used in a SoC based system.

The number, capability, and/or capacity of the elements of system 1850 may vary, depending on whether computing system 1850 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 1850 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: a plurality of columns of memory cells in an array, wherein each column of memory cells is coupled to a respective bit line and each respective bit line is coupled to a respective column select transistor; and for each column of memory cells, a respective footer transistor coupled to the memory cells, wherein a control gate of the respective footer transistor is coupled to a control gate of the respective column select transistor.

Example 2 includes the apparatus of Example 1, further comprising: for each column of memory cells, a path coupled to the memory cells and to the respective footer transistor.

Example 3 includes the apparatus of Example 2, wherein: for each column of memory cells, the path is coupled to sources of the memory cells, control gates of the memory cells are coupled to respective word lines in a set of word lines, and drains of the memory cells are coupled to the respective bit line.

Example 4 includes the apparatus of Example 2 or 3, wherein for each column of memory cells, the respective footer transistor, when turned on, is to ground the path and, when turned off, is to float a voltage of the path.

Example 5 includes the apparatus of any one of Examples 1-4, wherein: in a read operation for a selected column of the plurality of columns, a turn on signal is applied to the respective column select transistor and the respective footer transistor, while a turn off signal is applied to respective column select transistors of unselected columns of the plurality of columns and a voltage is increased on a selected word line.

Example 6 includes the apparatus of Example 5, wherein: when a selected memory cell of the selected column is in a low data state, the increase in the voltage of the selected word line creates a discharge path through the respective column select transistor of the selected column, the selected memory cell and the respective footer transistor of the selected column.

Example 7 includes the apparatus of Example 5 or 6, wherein: when a selected memory cell of the selected column is in a high data state, the selected memory cell will hold a high voltage and try to discharge through a leakage path bit line.

Example 8 includes the apparatus of any one of Examples 1-7, wherein: for each column of memory cells, a threshold voltage of the respective footer transistor and a threshold voltage of the column select transistor are lower than threshold voltages of the memory cells.

Example 9 includes the apparatus of any one of Examples 1-8, wherein: the memory cells comprise read-only memory (ROM) cells.

Example 10 includes the apparatus of any one of Examples 1-9, wherein: each respective column select transistor is an nMOS transistor and each respective footer transistor is an nMOS transistor.

Example 11 includes the apparatus of any one of Examples 1-10, wherein: each respective column select transistor and each respective footer transistor have a same polarity.

Example 12 includes an apparatus, comprising: a plurality of columns of memory cells in an array, wherein each column of memory cells is coupled to a respective bit line and each respective bit line is coupled to a respective column select transistor; and for each column of memory cells, a respective footer transistor coupled to the memory cells, wherein the respective footer transistors of the columns are independently controllable.

Example 13 includes the apparatus of Example 12, wherein: each respective footer transistor is controllable via a voltage on a respective control path.

Example 14 includes the apparatus of Example 12 or 13, wherein: for each column of memory cells, a control gate of the respective footer transistor is coupled to a control gate of the respective column select transistor.

Example 15 includes an apparatus, comprising: a memory device to store instructions; and a processor to execute the instructions to perform a read operation for a selected memory cell in a selected column of memory cells in an array, wherein: the selected column of memory cells is coupled to a bit line; a respective column select transistor is coupled to the bit line; a respective footer transistor is coupled to each memory cell in the selected column of memory cells; and to perform the read operation, the processor is to apply a turn on voltage to the respective footer transistor and the respective column select transistor of the selected column of memory cells, apply a turn off voltage to respective footer transistors and respective column select transistors of unselected column of memory cells in the array and increase a voltage on a selected word line.

Example 16 includes the apparatus of Example 15, wherein: when the selected memory cell is in a low data state, the increase in the voltage of the selected word line creates a discharge path through the respective column select transistor of the selected column, the selected memory cell and the respective footer transistor of the selected column.

Example 17 includes the apparatus of Example 15 or 16, wherein: when the selected memory cell is in a high data state, the selected memory cell will hold a high voltage and try to discharge through a leakage path bit line.

Example 18 includes the apparatus of any one of Examples 15-17, wherein: the respective footer transistor of the selected column of memory cells is to ground the selected column of memory cells when the turn on voltage is applied to the respective footer transistor of the selected column of memory cells.

Example 19 includes the apparatus of any one of Examples 15-18, wherein: the respective footer transistor of the selected column of memory cells is to float voltages of the selected column of memory cells when a turn off voltage is applied to the respective footer transistor of the selected column of memory cells.

Example 20 includes the apparatus of any one of Examples 15-19, wherein: a control gate of the respective footer transistor is coupled to a control gate of the respective column select transistor.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a plurality of columns of memory cells in an array, wherein each column of memory cells is coupled to a respective bit line and each respective bit line is coupled to a respective column select transistor; and
for each column of memory cells, a respective footer transistor coupled to the memory cells, wherein a control gate of the respective footer transistor is coupled to a control gate of the respective column select transistor.

2. The apparatus of claim 1, further comprising:
for each column of memory cells, a path coupled to the memory cells and to the respective footer transistor.

3. The apparatus of claim 2, wherein:
for each column of memory cells, the path is coupled to sources of the memory cells, control gates of the memory cells are coupled to respective word lines in a set of word lines, and drains of the memory cells are coupled to the respective bit line.

4. The apparatus of claim 2, wherein for each column of memory cells, the respective footer transistor, when turned on, is to ground the path and, when turned off, is to float a voltage of the path.

5. The apparatus of claim 1, wherein:
in a read operation for a selected column of the plurality of columns, a turn on signal is applied to the respective column select transistor and the respective footer transistor, while a turn off signal is applied to respective column select transistors of unselected columns of the plurality of columns and a voltage is increased on a selected word line.

6. The apparatus of claim 5, wherein:
when a selected memory cell of the selected column is in a low data state, the increase in the voltage of the selected word line creates a discharge path through the respective column select transistor of the selected column, the selected memory cell and the respective footer transistor of the selected column.

7. The apparatus of claim 5, wherein:
when a selected memory cell of the selected column is in a high data state, the selected memory cell will hold a high voltage and try to discharge through a leakage path bit line.

8. The apparatus of claim 1, wherein:
for each column of memory cells, a threshold voltage of the respective footer transistor and a threshold voltage of the column select transistor are lower than threshold voltages of the memory cells.

9. The apparatus of claim 1, wherein the memory cells comprise read-only memory (ROM) cells.

10. The apparatus of claim 1, wherein:
each respective column select transistor is an nMOS transistor and each respective footer transistor is an nMOS transistor.

11. The apparatus of claim 1, wherein:
each respective column select transistor and each respective footer transistor have a same polarity.

12. An apparatus, comprising:
a plurality of columns of memory cells in an array, wherein each column of memory cells is coupled to a respective bit line and each respective bit line is coupled to a respective column select transistor; and
for each column of memory cells, a respective footer transistor coupled to the memory cells, wherein the respective footer transistors of the columns are independently controllable.

13. The apparatus of claim 12, wherein each respective footer transistor is controllable via a voltage on a respective control path.

14. The apparatus of claim 12, wherein, for each column of memory cells, a control gate of the respective footer transistor is coupled to a control gate of the respective column select transistor.

15. An apparatus, comprising:
a memory device to store instructions; and
a processor to execute the instructions to perform a read operation for a selected memory cell in a selected column of memory cells in an array, wherein:
the selected column of memory cells is coupled to a bit line;
a respective column select transistor is coupled to the bit line;
a respective footer transistor is coupled to each memory cell in the selected column of memory cells; and
to perform the read operation, the processor is to apply a turn on voltage to the respective footer transistor and the respective column select transistor of the selected column of memory cells, apply a turn off voltage to respective footer transistors and respective column select transistors of unselected column of memory cells in the array and increase a voltage on a selected word line.

16. The apparatus of claim 15, wherein when the selected memory cell is in a low data state, the increase in the voltage of the selected word line creates a discharge path through the respective column select transistor of the selected column, the selected memory cell and the respective footer transistor of the selected column.

17. The apparatus of claim 15, wherein when the selected memory cell is in a high data state, the selected memory cell will hold a high voltage and try to discharge through a leakage path bit line.

18. The apparatus of claim 15, wherein:
the respective footer transistor of the selected column of memory cells is to ground the selected column of memory cells when the turn on voltage is applied to the respective footer transistor of the selected column of memory cells.

19. The apparatus of claim 15, wherein:
the respective footer transistor of the selected column of memory cells is to float voltages of the selected column of memory cells when a turn off voltage is applied to the respective footer transistor of the selected column of memory cells.

20. The apparatus of claim 15, wherein:
a control gate of the respective footer transistor is coupled to a control gate of the respective column select transistor.
